(19) United States
(12) Patent Application Publication
(10) Pub. No.: US 2026/0143726 A1
(43) Pub. Date: May 21, 2026

(54) CAPACITOR

(71) Applicant: GlobalFoundries U.S. Inc., Malta, NY (US)

(72) Inventors: Teng-Yin Lin, Clifton Park, NY (US); Tamilmani Ethirajan, Guilderland, NY (US); Kaustubh Shanbhag, Slingerlands, NY (US); Vibhor Jain, Clifton Park, NY (US)

(21) Appl. No.: 18/952,098

(22) Filed: Nov. 19, 2024

(51) Int. Cl. H01L 29/94; H01L 29/06; H01L 29/66

(52) U.S. Cl. CPC H10D 1/66; H10D 1/047; H10D 1/692; H10D 62/115

(57) ABSTRACT

The present disclosure relates to semiconductor structures and, more particularly, to capacitor structures and methods of manufacture. The structure includes: a gate structure over an active region of a semiconductor substrate; a source region on a first side of the gate structure; a drain region on a second side of the gate structure; a first contact structure shorting the drain region to the source region by; and a second contact structure connecting to the gate structure over the active region.

### BACKGROUND

The present disclosure relates to semiconductor structures and, more particularly, to capacitor structures and methods of manufacture.

A metal oxide semiconductor Capacitor (MOSCAP) includes an insulator material (e.g., gate dielectric material) between a metal gate and a semiconductor material. Depending on the type (doping) of the semiconductor material and the voltage applied on the metal gate, the MOSCAP has three modes of operation. In one mode, the voltage applied on the metal contact accumulates majority carriers on the surface of the semiconductor and this is called “Accumulation.” In the other case, the applied voltage induces minority carriers on the semiconductor surface. This initially creates a depletion region at the surface (the “Depletion” mode of operation) and eventually the majority carrier type at the surface of the semiconductor gets inverted. This final mode is called the “Inversion.”

### SUMMARY

In an aspect of the disclosure, a structure comprises: a gate structure over an active region of a semiconductor substrate; a source region on a first side of the gate structure; a drain region on a second side of the gate structure; a first contact structure shorting the drain region to the source region by; and a second contact structure connecting to the gate structure over the active region.

In an aspect of the disclosure, a structure comprises: an active region of a semiconductor substrate; a shallow trench isolation structure in the semiconductor substrate; a gate structure comprising a gate dielectric material and a gate electrode, the gate structure being at least over the active region; a source region adjacent to the gate structure; a drain region shorted to the source region; and a conductive structure connecting to the gate structure over the active region.

In an aspect of the disclosure, a method comprises: forming a gate structure over an active region of a semiconductor substrate; forming a source region on a first side of the gate structure; forming a drain region on a second side of the gate structure; forming a first contact structure shorting the drain region to the source region by; and forming a second contact structure connecting to the gate structure over the active region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1A shows a first cross-sectional view of a structure and respective fabrication processes in accordance with aspects of the present disclosure.

FIG. 1B shows a second cross-sectional view of the structure of FIG. 1A.

FIGS. 2-4 show alternative structures and respective fabrication processes in accordance with aspects of the present disclosure.

### DETAILED DESCRIPTION

The present disclosure relates to semiconductor structures and, more particularly, to capacitor structures and methods of manufacture. More specifically, the present disclosure relates to a metal oxide semiconductor capacitor (MOSCAP). In embodiments, the capacitor includes a gate structure over an active region, e.g., a well formed in the semiconductor substrate, with contacts connecting to the gate structure and contacts connecting to adjacent source/drain regions. In embodiments, the contacts to the source region and drain region will be shorted to form a first electrode of the capacitor structure; whereas the contact to the gate structure over the active region will be a second electrode. In embodiments, the first electrode and second electrode can be independently biased thereby forming a capacitor structure. Advantageously, the present disclosure provides a tunable capacitor by adjusting a gate length or dimension of the contacts, in addition to exhibiting a high Q factor, i.e., low energy loss and increased capacitance.

The structure of the present disclosure can be manufactured in a number of ways using a number of different tools. In general, though, the methodologies and tools are used to form structures with dimensions in the micrometer and nanometer scale. The methodologies, i.e., technologies, employed to manufacture the structure of the present disclosure have been adopted from integrated circuit (IC) technology. For example, the structures are built on wafers and are realized in films of material patterned by photolithographic processes on the top of a wafer. In particular, the fabrication of the structure uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

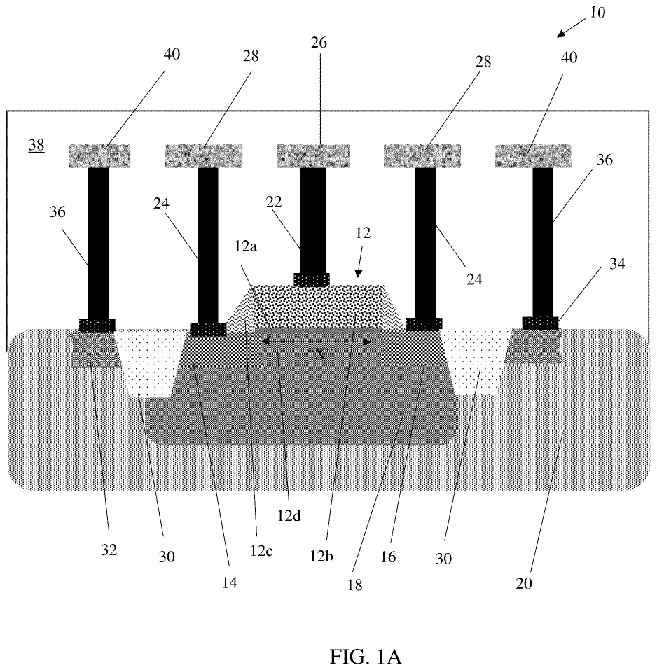

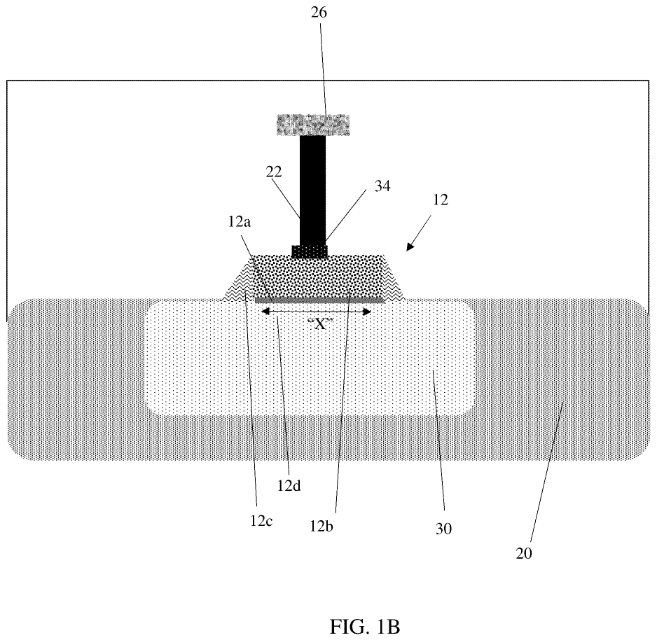

FIG. 1A shows a first cross-sectional view of a structure and respective fabrication processes in accordance with aspects of the present disclosure. FIG. 1B shows a second cross-sectional view of the structure of FIG. 1A. For example, FIG. 1A shows a gate structure over an active region electrically connected to a contact and wiring structure; whereas FIG. 1B shows the gate structure over a shallow trench isolation structure electrically connected to the contact and wiring structure.

More specifically and referring to FIG. 1A, the structure 10 includes a gate structure 12 and an adjacent source region 14 shorted to an adjacent drain region 16. In embodiments, the gate structure 12 is provided over an active region 18 in a semiconductor substrate 20. A contact 22 may be provided to the gate structure 12 and contacts 24 may be provided to both the source region 14 and the drain region 16. In embodiments, the contacts 22, 24 may connect to different wiring structures 26, 28, respectively, with the wiring structure 28 electrically shorting the source region 14 to the drain region 16. In this way, the wiring structure 28 may be connected to a first electrode and the wiring structure 26 may be connected to a second electrode, which can be independently biased.

In more specific embodiments, the structure 10 comprises a semiconductor substrate 20 composed of any suitable material including, but not limited to, Si, SiGe, SiGeC, SiC, GaAs, InAs, InP, and other III/V or II/VI compound semiconductors. In embodiments, the semiconductor substrate 20 may be a p-type semiconductor substrate with a suitable single crystallographic orientation (e.g., a (100), (110), (111), or (001) crystallographic orientation).

The semiconductor substrate 20 may be a bulk substrate or semiconductor-on-insulator (SOI) technology. In the SOI technology, a handle substrate and the semiconductor substrate 14 may include the same semiconductor material as noted herein. As is known in the art, the handle substrate provides mechanical support to a buried insulator layer and the top semiconductor layer, e.g., semiconductor substrate 20. The buried insulator layer may include a dielectric material such as silicon dioxide, silicon nitride, silicon oxynitride, boron nitride or a combination thereof. In one preferred embodiment, the buried insulator layer may be a buried oxide layer formed by a deposition process, such as chemical vapor deposition (CVD), plasma enhanced chemical vapor deposition CVD (PECVD) or physical vapor deposition (PVD), or a thermal growth process as is known in the art such that no further explanation is required herein for a complete understanding of the present disclosure.

A well 18 may be formed in the semiconductor substrate 20. In embodiments, the well 18 may be an active region of the device, which is bounded by shallow trench isolation structures 30. In embodiments, the well 18 may be isolated from other structures by the shallow trench isolation structures 30. For example, the shallow trench isolation structures 30 may be provided about, e.g., surrounding the n-well 18. In alternative embodiments, the well 18 may be an n-well for a p-type substrate or a p-well for an n-type semiconductor substrate.

The well 18 may be formed by an ion implantation process. For example, a patterned implantation mask may be used to define selected areas exposed for the implantation, e.g., well 18. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block the masked area against receiving a dose of the implanted ions. The well 18 may be doped with n-type dopants, e.g., Arsenic (As), Phosphorus (P) and Antimony (Sb), among other suitable examples.

The shallow trench isolation structures 30 can be formed by conventional lithography, etching and deposition methods known to those of skill in the art. For example, a resist formed over the semiconductor substrate 20 is exposed to energy (light) and developed utilizing a conventional resist developer to form a pattern (opening(s)). An etching process with a selective chemistry, e.g., reactive ion etching (RIE), will be used to transfer the pattern to form one or more trenches in the semiconductor substrate 20 through the openings of the resist. Following the resist removal by a conventional oxygen ashing process or other known stripants, insulator material, e.g., oxide, can be deposited by any conventional deposition processes, e.g., chemical vapor deposition (CVD) processes. Any residual material on the surface of the semiconductor substrate 20 can be removed by conventional chemical mechanical polishing (CMP) processes.

FIG. 1A further shows the gate structure 12 over the semiconductor substrate 20 and within (e.g., over) the active region, e.g., over the well 18. The gate structure 12 may be positioned between the source region 14 and the drain region 16. In embodiments, the gate structure 12 includes a gate dielectric material 12a and a gate electrode 12b. In embodiments, the gate dielectric material 12a may be a low-k dielectric material such as oxide. The gate electrode material 12b may be a polysilicon material. In embodiments, the polysilicon material can be n+ doped material (when over an n-well) or p+ doped material (when over a p-well). Sidewall spacers 12c are formed on the sidewalls on the gate structure 12, e.g., gate dielectric material 12a and gate electrode 12b. The sidewall spacers 12c may be oxide and/or nitride material.

A channel region 12d in the semiconductor material 20 may be provided between the source region 14 and the drain region 16, under the gate structure 12. The channel length “X” of the channel region 12d can be tuned, e.g., have different dimensions, depending on the required device capacitance. In embodiments, for example, the channel region, e.g., gate length “X”, can be 2× or 3× of the minimum ground rules for a particular technology node. In this way, the wiring structure 26 and via interconnect structure 22 can connect directly to the gate structure 12 within the active region, e.g., over the well 18 (which is not otherwise achievable in current technologies).

Although not critical to the understanding of the present disclosure, the gate structure 12 can be fabricated using conventional CMOS processes. In the standard CMOS processing, the gate dielectric material 12a and gate electrode material 12b, e.g., polysilicon material, are formed, e.g., deposited, on the semiconductor substrate 20, followed by a patterning process. An insulator material such as nitride or oxide can be deposited on the patterned materials, followed by an anisotropic etching process to form the sidewall structures 12c. The gate dielectric 12a may be deposited by a conventional CVD process or, alternatively, an atomic layer deposition (ALD) or plasma-enhanced CVD (PECVD) as other examples. The gate structure 12 can be formed with the same material and during the same processes as active gate structures. The material of the sidewall structures 12c may be deposited by a CVD process, with the sidewall structures 12c being patterned by an anisotropic etching process as is known in the art.

The source region 14 and the drain region 16 may be formed by ion implantation processes as described herein such that no further explanation is required for a complete understanding of the present disclosure. Alternatively, the source region 14 and the drain region 16 may be formed by an epitaxial growth process with an in-situ doping process to form a raised source region and a raised drain region as is known in the art. In embodiments, epitaxy regions (source/drain regions) may be any appropriate semiconductor material, e.g., Si or III-V compound semiconductor materials, combinations thereof, or multi-layers thereof. The in-situ doping process may include any appropriate dopant type, e.g., n-type impurity. An annealing process may be performed to drive in the dopant into the semiconductor substrate 20, e.g., into the well 18.

FIG. 1A further shows p+ diffusion regions 32 in the semiconductor substrate 20. In embodiments, the shallow trench isolation structures 30 will isolate the p+ diffusion regions 32 from the source region 14 and the drain region 16, respectively. The p+ diffusion regions 32 may be formed by an ion implantation process as already described herein such that no further explanation is required for a complete understanding of the present disclosure.

Silicide contacts 34 may be provided in contact with the source region 14, drain region 16, gate electrode 12b, and the p+diffusion regions 32. As should be understood by those of skill in the art, the silicide process begins with deposition of a thin transition metal layer, e.g., nickel, cobalt or titanium, over fully formed and patterned semiconductor devices (e.g., source region 14, drain region 16, gate electrode 12b, and the p+diffusion regions 32). After deposition of the material, the structure is heated allowing the transition metal to react with exposed silicon (or other semiconductor material as described herein) in the active regions of the semiconductor device (e.g., source region 14, drain region 16, gate electrode 12b, and the p+diffusion regions 32) forming a low-resistance transition metal silicide. Following the reaction, any remaining transition metal is removed by chemical etching, leaving silicide contacts 34.

As further shown in FIG. 1A, via interconnect structures (e.g., contacts) 22, 24, 36 may contact the silicide contacts 34. In embodiments, the via interconnect structure 22 may be a different height, e.g., higher or lower, than the via interconnect structure 24 to adjust device capacitance.

The via interconnect structures 22, 24, 36 may be formed by conventional lithography, etching and deposition methods known to those of skill in the art. For example, a resist formed over an insulator material 38 is exposed to energy (light) and developed utilizing a conventional resist developer to form a pattern (opening). An etching process with a selective chemistry, e.g., reactive ion etching (RIE), will be used to transfer the pattern from the photoresist layer to the insulator material 38 (e.g., interlevel dielectric material) to form one or more trenches in the insulator material 38. Following the resist removal by a conventional oxygen ashing process or other known stripants, conductive material can be deposited by any conventional deposition processes, e.g., chemical vapor deposition (CVD) processes. The conductive material may be, for example, tungsten, TiN, TaN, etc. Any residual material on the surface of the insulator material 38 can be removed by conventional chemical mechanical polishing (CMP) processes.

Wiring structures 26, 28, 40 may be provided in contact to the via interconnect structures 22, 24, 36. As should be understood by those of ordinary skill in the art, the wiring structures 26, 28 and the respective via interconnect structures 22, 24 may form contact structures to the respective gate structure 12 and the source and drain regions 14, 16. The wiring structures 26, 28, 40 may be a first level wiring structure, although other level wiring structures are contemplated herein. In embodiments, the wiring structures 26, 28, 40 may be formed by conventional lithography, etching and deposition methods known to those of skill in the art and as already described herein. The wiring structures 22, 24, 26 may be any conventional conductive material used for wiring structures, e.g., copper, aluminum, etc. In embodiments, the wiring structure 28 will short the source region 14 and the drain region 16, whereas the wiring structure 26 will form an electrode to the gate structure 12. In embodiments, the wiring structures 26, 28 can be independently biased to form the capacitor structure.

In the cross-sectional view of FIG. 1B, the gate structure 12 may also be provided over the shallow trench isolation structure 30. That is, the gate structure 12 is not over an active region of the device. The gate structure 12 includes the gate dielectric material 12a, gate electrode 12b and sidewall spacers 12d. Also, as shown in this view, the via interconnect structure 22 and wiring structure 26 are connected to the gate electrode 12b (over the shallow trench isolation structure).

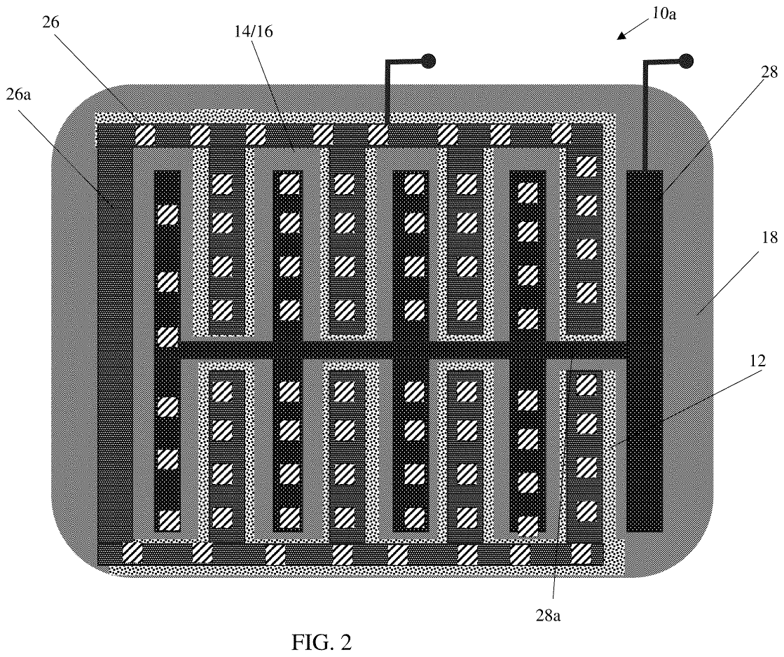

FIG. 2 shows a top view of a structure in accordance with additional aspects of the present disclosure. In the structure 10a shown in FIG. 2, the wiring structure 26 connects to two gate structures 12 and the wiring structure 28 connects to both the source region 14 and the drain region 16. The gate structures 12 may be two comb structures located on opposing sides of a segment 28a of the wiring structure 28. Also, the wiring structure 26, 28 may be interleaved with one another. Further, the wiring structure 28 may include a segment 28a connecting the wiring structure 28 located over both the gate structures 12. As should be understood by those of skill in the art and as in any of the embodiments, the wiring structures 26, 28 may be on the same or a different wiring level, in any combination. Moreover, different segments of the wiring structure 26 may be on different wiring levels and, similarly, different segments of the wiring structure 28 may be on different wiring levels.

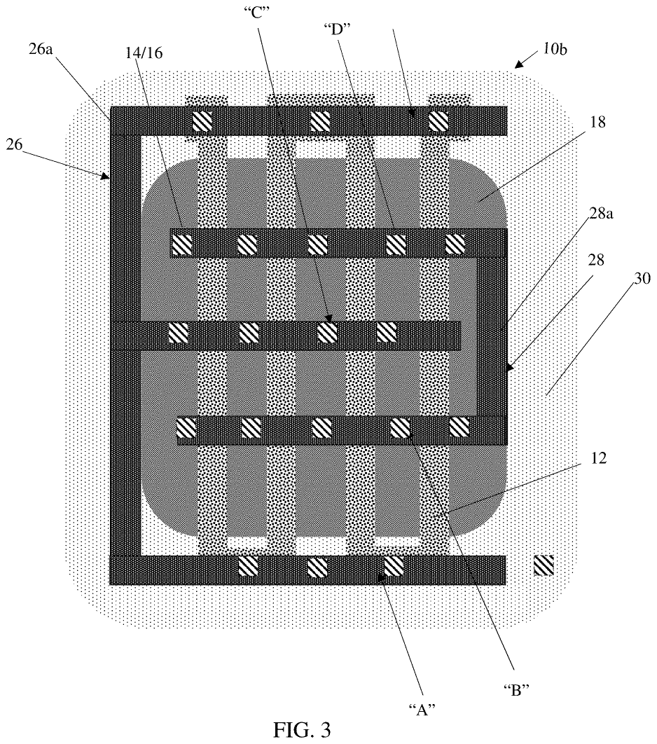

FIG. 3 shows a top view of a structure in accordance with further aspects of the present disclosure. In the structure 10b shown in FIG. 3, the wiring structure 26 connects to the gate structure 12 over both the active region 18 and the shallow trench isolation structure 30 (by use of the via interconnect structures 22 (not shown in this view)), whereas the wiring structure 28 connects to both the source region 14 and the drain region 16 in the active region 18 (by use of the via interconnect structures 24 (not shown in this view)). In this embodiment, the gate structure 12 may be a serpentine shape, for example, and the wiring structures 26, 28 may include segments 26b, 28b perpendicular to and crossing over portions of the gate structure 12.

Also, in embodiments, the by virtue of the wiring structures 26, 28 being on different rows, the via interconnect structures 22, 24 connect to the source region 14, drain region 16 and the gate structure 12 in different rows to prevent shorts between the via interconnect structures 22, 24. For example, the wiring structures 26, 28 are representatively shown with parallel rows “A”, “B”, “C”, “D”, “E”, with rows “A”, “C”, “E” of wiring structure 26 having the interconnect structures 22 to the gate structures 12 and rows “B”, “D” of wiring structure 28 having the interconnect structures 24 to the source and drain regions 14, 16. The wiring structures 26, 28 may also include respective segments 26a, 28a parallel to portions of the gate structure 12 and connecting to the perpendicular segments, e.g., parallel rows “A”, “B”, “C”, “D”, “E”, of the wiring structures 26, 28.

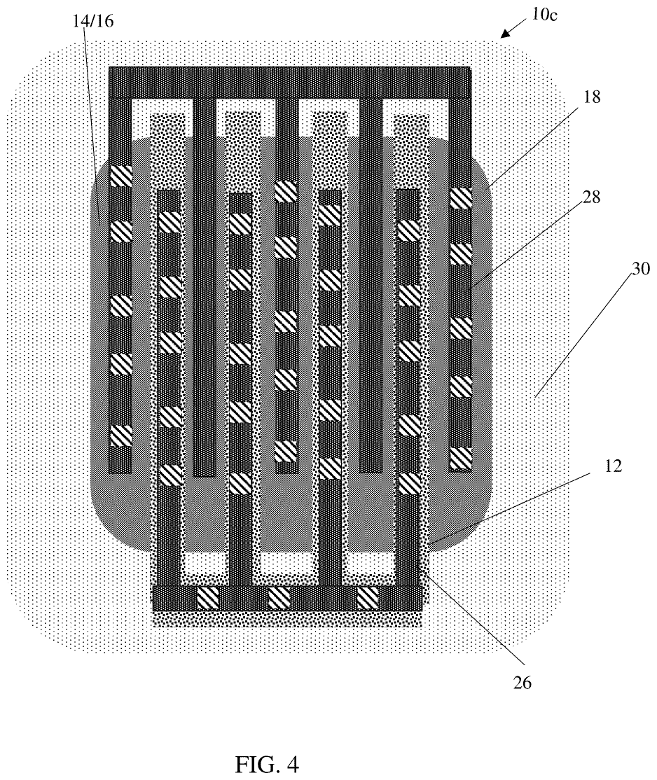

FIG. 4 shows a top view of a structure in accordance with additional aspects of the present disclosure. In the structure 10c shown in FIG. 4, the wiring structure 26 connects to the gate structure 12 over both the active region 18 and the shallow trench isolation structure 30 (by use of the via interconnect structures 22 (not shown in this view)), whereas the wiring structure 28 connects to both the source region 14 and the drain region 16 in the active region 18 (by use of the via interconnect structures 24 (not shown in this view)). In this embodiment, the gate structure 12 may be a comb structure, for example, with the wiring structure 28 interleaved with wiring structure 26 on the same or a different wiring level.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multichip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprises:
a gate structure over an active region of a semiconductor substrate;
a source region on a first side of the gate structure;
a drain region on a second side of the gate structure;
a first contact structure shorting the drain region to the source region by; and
a second contact structure connecting to the gate structure over the active region.

2. The structure of claim 1, wherein the first contact and the second contact are respective electrodes which independently bias.

3. The structure of claim 1, wherein:
the first contact structure comprises via interconnect structures to the drain region and the source region, with a wiring structure connecting to the via interconnect structures; and
the second contact structure comprises a via interconnect structure and a wiring structure.

4. The structure of claim 3, wherein the via interconnect structure of the first contact structure is at a different height than the via interconnect structures from the second contact structure.

5. The structure of claim 3, wherein the via interconnect structure of the first contact structure is a same height as the via interconnect structures from the second contact structure.

6. The structure of claim 1, wherein the gate structure is over a shallow trench isolation structure.

7. The structure of claim 1, wherein the second contact structure connects to the gate structure over the shallow trench isolation structure.

8. The structure of claim 1, wherein the gate structure comprises a serpentine shape.

9. The structure of claim 1, wherein the gate structure comprises a comb structure.

10. The structure of claim 1, wherein the first contact structure is provided on a different wiring row than the second contact structure.

11. The structure of claim 1, wherein the first contact structure and the second contact structure are on a same wiring level.

12. The structure of claim 1, wherein the first contact structure and the second contact structure are on a different wiring level.

13. The structure of claim 1, wherein the first contact structure comprising a first wiring structure, the second contact structure comprises a second wiring structure and the first wiring structure and the second wiring structure are interleaved with one another.

14. A structure comprising:
an active region of a semiconductor substrate;
a shallow trench isolation structure in the semiconductor substrate;
a gate structure comprising a gate dielectric material and a gate electrode, the gate structure being at least over the active region;
a source region adjacent to the gate structure;
a drain region shorted to the source region; and
a conductive structure connecting to the gate structure over the active region.

15. The structure of claim 14, wherein the conductive structure comprises a via interconnect structure and a wiring structure.

16. The structure of claim 15, wherein the source and drain region are shorted by a at least one via interconnect structure and a wiring structure.

17. The structure of claim 16, wherein the at least one via interconnect structure is at a different height than the via interconnect structure of the conductive structure connecting to the gate structure.

18. The structure of claim 15, wherein the via interconnect structure connecting to the gate structure is provided at a different row of a device layout than the at least one via interconnect structure.

19. The structure of claim 14, wherein the gate structure comprises one of a serpentine shape and a comb shape.

20. A method comprises:
forming a gate structure over an active region of a semiconductor substrate;
forming a source region on a first side of the gate structure;
forming a drain region on a second side of the gate structure;
forming a first contact structure shorting the drain region to the source region by; and
forming a second contact structure connecting to the gate structure over the active region.
